(19) United States
(12) Patent Application Publication
(10) Pub. No.: US 2005/0196904 A1
(43) Pub. Date: Sep. 8, 2005

(54) Aerodynamic memory module cover

(76) Inventors: Anandaroop Bhattacharya, Phoenix, AZ (US); Chia-Pin Chiu, Tempe, AZ (US)

Correspondence Address: TROP PRUNER & HU, PC, 8554 KATY FREEWAY, SUITE 100, HOUSTON, TX, 77024, US

(21) Appl. No.: 10/794,129

(22) Filed: Mar. 5, 2004

(51) Int. Cl. H01L 23/12; H01L 21/48

(52) U.S. Cl. 438/125; 257/704

(57) ABSTRACT

Adjacent integrated circuit chips in processor-based systems may be covered with a metal foil cover. The cover may make air flow over the chips more aerodynamic, improving thermal heat transfer and cooling. This may improve performance and reduce power consumption, all without significantly increasing the size of the components.

### BACKGROUND

This invention relates generally to cooling processor-based systems.

Processor-based systems are subject to the generation of relatively high temperatures. These temperatures are the result of heating by semiconductor integrated circuits included in such processor-based systems.

Particularly in mobile systems, the space available for cooling is relatively small. Therefore, overheating may become a major concern. Overheating may result in device failure or in performance degradation.

Existing cooling techniques for processor-based systems may use fans. One problem is that upstream integrated circuits are cooled more effectively than downstream integrated circuits. As the air goes downstream, it faces higher flow resistance and tends to bypass the hotter downstream components. As a result, the flow rates of the fan or the air moving device need to be increased, resulting in higher power consumption, vibration, and noise.

Thus, there is a need for better ways to cool processor-based systems.

### BRIEF DESCRIPTION OF THE DRAWINGS

FIG. 1 is a cross-sectional view of one embodiment of the present invention.

### DETAILED DESCRIPTION

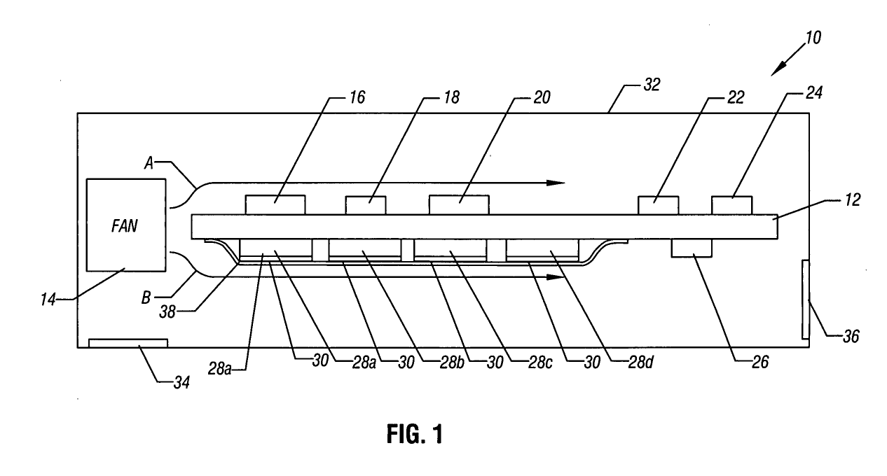

Referring to FIG. 1, a processor-based system 10 may be a laptop computer, a desktop computer, a handheld computer, such as a personal digital assistant or a cellular telephone, an entertainment device, an entertainment system, or any of a variety of other systems using processors.

The system 10 may include a housing 32 having an input vent 34 and an output vent 36. Air is circulated by a fan 14 over the top and bottom of the motherboard 12. Any source of airflow may be used in place of the fan 14 including a blower, a piezoelectric fan, or a vibrating membrane, to mention a few examples. In one embodiment, the motherboard 12 may include components on its upper surface, such as a processor 16, a voltage regulator 18, an memory controller hub (MCH) 20, a graphics accelerator 22, and a system voltage regulator 24. The lower surface of the motherboard 12 may include an input/output controller hub (ICH) 26 and a number of adjacent memory chips 28.

In other embodiments, the memory chips 28 may be located on a card or board separate from the motherboard 12.

Each memory chip 28 may have, on its outwardly facing surface, a thermal interface material 30. Bonded over the thermal interface material 30 is a cover 38. The cover 38 may be a metal foil adhesively secured at each end of the motherboard 12 and may be adhesively secured to the thermal interface material 30 in one embodiment.

In some embodiments, the material 30 may be high heat conducting adhesive. The cover 38 may be formed of copper or aluminum foil, as two examples.

The film 38 makes the air flow over the memory chips 28 more aerodynamic or laminar. As a result of the provision of the cover 38, the airflow is smoothed out, reducing flow resistance. This may result in more efficient cooling.

In some cases, the cover 38 may be sufficiently thick to aid in heat spreading. In one embodiment, the cover 38 thickness may range between 0.2 millimeters and 0.5 millimeters.

In some embodiments, the use of the cover 38 may reduce die temperatures, enabling higher power memory modules to be placed in notebook and desktop computers. In some cases, thermal performance may be improved without substantially increasing the size of the electronic device. Also, in some embodiments, cooling farther from the fan may be made more efficient.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
covering at least two integrated circuit chips with a cover.

2. The method of claim 1 including covering at least two integrated circuit chips with a metal foil cover.

3. The method of claim 1 including adhesively securing said cover to a printed circuit board.

4. The method of claim 3 including adhesively securing said cover to said integrated circuit chips.

5. A method comprising:
covering at least two integrated circuit chips on a printed circuit board with a metal foil cover; and
enabling air to be blown over said integrated circuit chips.

6. The method of claim 5 including adhesively securing said cover to a printed circuit board.

7. The method of claim 6 including adhesively securing said cover to said integrated circuit chips.

8. A printed circuit board comprising:
at least two integrated circuit chips secured to said printed circuit board; and
a cover over at least said two integrated circuit chips.

9. The board of claim 8 wherein said cover is a metal foil cover.

10. The board of claim 8 wherein said cover is adhesively secured to said board.

11. The board of claim 8 wherein said cover is adhesively secured to said chips.

12. A processor-based system comprising:
a printed circuit board;
at least two integrated circuit chips secured to said printed circuit board; and
a cover over said two integrated circuit chips.

13. The system of claim 12 wherein said cover is a metal foil cover.

14. The system of claim 12 wherein said cover is adhesively secured to said board.

15. The system of claim 12 wherein said cover is adhesively secured to said chips.
